(19) United States
(12) Patent Application Publication
(10) Pub. No.: US 2007/0066084 A1
(43) Pub. Date: Mar. 22, 2007

(54) Method and system for forming a layer with controllable spstial variation

(76) Inventors: Cory Wajda, Sand Lake, NY (US); David L. O'Meara, Poughkeepsie, NY (US); Masanobu Igeta, Fishkill, NY (US)

Correspondence Address: DLA PIPER US LLP, P. O. BOX 9271, RESTON, VA, 20195, US

(21) Appl. No.: 11/231,335

(22) Filed: Sep. 21, 2005

(51) Int. Cl. H01L 21/471; B05C 5/00

(52) U.S. Cl. 438/765; 438/771; 118/72; 118/620

(57) ABSTRACT

A method and processing system for treating a surface of a substrate. The surface is exposed to at least two radicals from at least two radical sources. The radicals generated from the respective radical sources interact with different areas of the substrate surface. The invention suitably improves uniformity of oxidation, nitridation, or both.

### BACKGROUND OF THE INVENTION

### Field of the Invention

The present invention generally relates to methods and systems suitable for producing electronic devices and materials used for electronic devices.

### BRIEF SUMMARY OF THE INVENTION

The present invention generally relates to a method and processing system for preparing an oxide, nitride, oxynitride, or other film on a substrate. A surface of a substrate is exposed to at least two radicals from at least two radical sources. The radicals generated from the respective radical sources interact with different areas of the substrate surface. The invention suitably improves uniformity of oxidation, nitridation, or both.

### BRIEF DESCRIPTION OF THE FIGURES

FIG. 1 illustrates one embodiment of a processing system for forming a layer on a substrate.

FIG. 2 illustrates one embodiment of a schematic diagram of a processing system for forming a layer on a substrate.

FIG. 3 illustrates another embodiment of a schematic diagram of a processing system.

FIG. 4 illustrates yet another embodiment of a schematic diagram of a processing system.

FIG. 5 illustrates yet another embodiment of a schematic diagram of a processing system.

### DETAILED DESCRIPTION OF SEVERAL EMBODIMENTS

Treatment System

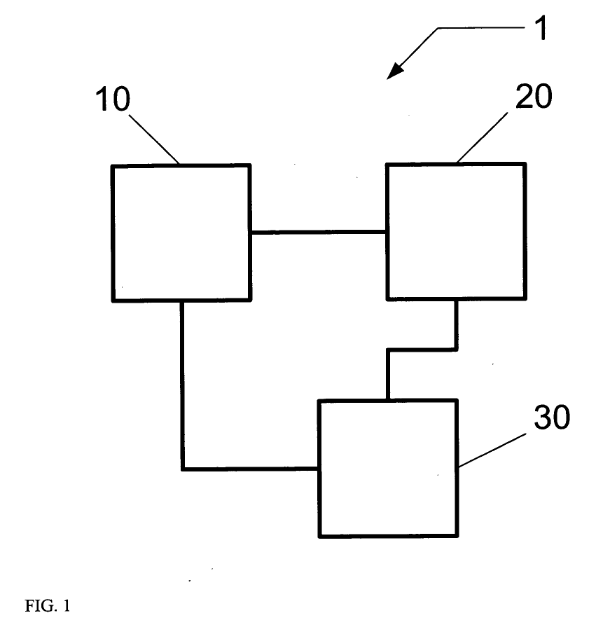

FIG. 1 illustrates a treatment system 1 for forming one or more layers on a substrate or for treating a substrate. The treatment system 1 comprises an oxidation system 10 configured to introduce an oxygen radical or an oxygen-containing molecular composition to the substrate, and an oxidation and/or nitridation system 20 configured to introduce oxygen and/or nitrogen radicals or an oxygen- and/or nitrogen-containing molecular composition to the substrate in the case of subsequent oxidation, nitridation or oxynitridation. Additionally, treatment system 1 further comprises a controller 30 coupled to the oxidation system 10 and the oxidation and/or nitridation system 20, and configured to perform at least one of monitoring, adjusting, or controlling the process(es) performed in the oxidation system 10 and the oxidation and/or nitridation system 20. Although the oxidation system 10 and the oxidation and/or nitridation system 20 are illustrated as separate modules in FIG. 1, they may comprise the same module.

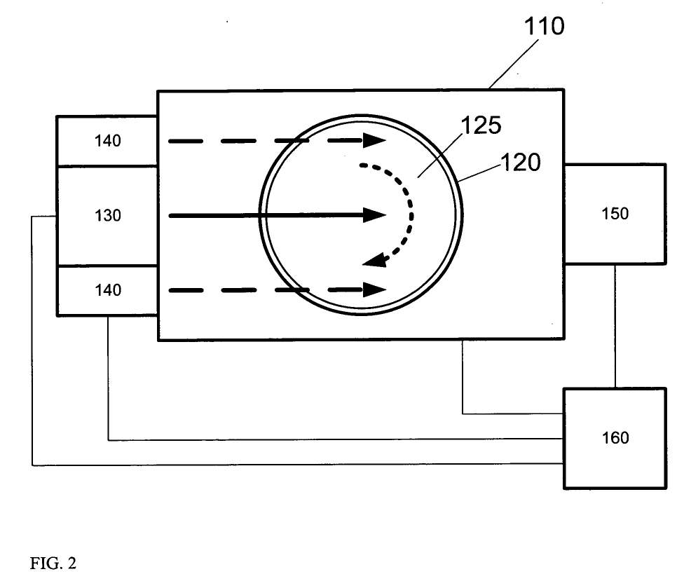

FIG. 2 illustrates a schematic top view of one embodiment of a processing system for forming a layer or treating a substrate. The processing system may be configured to perform an oxidation, nitridation, oxynitridation, or other treatment of a substrate 125. The processing system comprises a treatment chamber 110, a substrate holder 120 configured to support substrate 125, a first radical source 130 configured to introduce a first flow of one or more radicals to a substantially central portion of substrate 125, a second radical source 140 configured to introduce a second flow of one or more radicals to a substantially edge portion of substrate 125, a pumping system 150, and a controller 160. The first radical source 130 can include, for example, a remote plasma source configured to form the first flow of radicals from a first process gas by plasma-induced dissociation of the first process gas, or it may include, for example, an ultraviolet (UV) radiation source configured to dissociate the first process gas to form a second flow of a radical within treatment chamber 110. The second radical source 140 can include, for example, a remote plasma source configured to form the second flow of radicals from a second process gas by plasma-induced dissociation of the second process gas, or it may include, for example, an ultraviolet (UV) radiation source configured to dissociate the second process gas to form the second flow of radicals within treatment chamber 110. The first and second process gases can, for example, include O₂ for an oxidation process, N₂ for a nitridation process, or N₂ and O₂, NO, NO₂, or N₂O for both an oxidation and a nitridation process. A plurality of process gases may be used, in any combination.

Substrate 125 rests on top of substrate holder 120. It may or may not be clamped. It may be temperature controlled. Substrate 125 can be rotated to improve uniformity azimuthally.

The controller 160, for example, can be configured to control one or more of a flow rate of the first process gas, the intensity (or power) of the first radical source 130 (e.g., UV intensity from a UV source, or power input to a plasma source), the flow rate of the second process gas, or the intensity (or power) of the second radical source 140 in order to affect a change in the uniformity of the oxidation or nitridation process. Alternatively, or in addition, the controller 160 may be configured to control any other parameter of the treatment chamber 110. The controller 160 can also be configured to independently control each of the second radical sources 140 relative to one another. A plurality of first radical sources 130 may be used, including 2, 3, 4, 5, or 6 first radical sources 130. Similarly, more than one second radical source 140 may be used, including 2, 3, 4, 5, 6, or 7 second radical sources 140. Each radical source may be independently controlled with the controller 160. Controller 160 also can control pumping system 150. More than one controller 160 may be used.

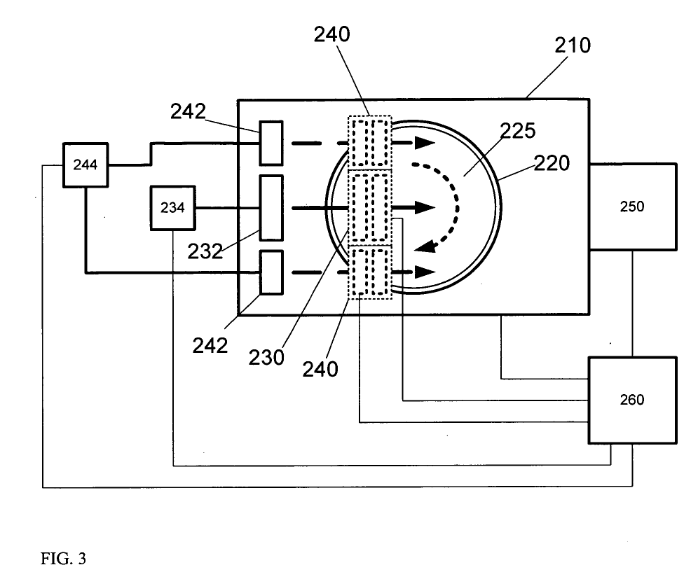

FIG. 3 illustrates a schematic top view of one embodiment of a processing system for forming a layer or treating a substrate. The processing system may be configured to perform an oxidation, nitridation, oxynitridation, or other treatment of a substrate 225. The processing system comprises a treatment chamber 210, a substrate holder 220 configured to support substrate 225, a first radical source 230 configured to introduce a first flow of one or more radicals to a substantially central portion of substrate 225, a second radical source 240 configured to introduce a second flow of one or more radicals to a substantially edge portion of substrate 225, a pumping system 250, and a controller 260. A first gas supply system 232 is configured to supply a first process gas to treatment chamber 210 through a first gas injection system 234 (e.g., a gas injection rake). The first radical source 230 may include a first array of UV lamps (e.g., the array of UV lamps may include one or more lamps, including 2, 3, 4, 5, 6, 7, or 8 lamps). A plurality of UV lamp arrays are possible, including 2, 3, 4, 5, 6, 7, or 8 arrays). In one embodiment, the processing system is configured such that the first flow of radicals is generated by UV radiation induced dissociation of the first process gas by the UV lamps. Alternatively, or additionally, the first radical source 230 can include one or more non-UV radical sources, such as one or more remote or local plasma induced dissociation sources, or other radical source described herein.

A second gas supply system 242 is configured to supply a second process gas to treatment chamber 210 through a second gas injection system 244 (e.g., a gas injection rake). The second radical source 240 includes a second array of UV lamps. Alternatively, or additionally, the second radical source 240 can include one or more non-UV radical sources, such as one or more remote or local plasma induced dissociation sources, or other radical source described herein.

A plurality of first and second gas supply systems 232 and 242 can independently be used, which can include 2, 3, 4, 5, or 6 first gas supply system 232, and 2, 3, 4, 5, or 6 second gas supply systems 242. A plurality of first and second gas injection systems 234 and 244 can be used, which can include 2, 3, 4, 5, or 6 first gas injection system 234, and 2, 3, 4, 5, or 6 second gas injection systems 244.

The first and second radical flows may each independently include any radicals, oxygen radicals, nitrogen radicals, molecular radicals of oxygen and nitrogen, or any combination thereof, to effect oxidation, nitridation, oxynitridation, other treatment, or any combination thereof.

The first and second gas supply and gas injection systems, 232, 242, 234, 244, may be independently configured to introduce one or more than one process gas. Examples of process gases include, for example, O₂ for an oxidation process, N₂ for a nitridation process, or N₂ and O₂, NO, NO₂, or N₂O, or any combination thereof, for both an oxidation and a nitridation process.

The controller 260 can, for example, be configured to individually control the first and second radical sources 230 and 240 (e.g., UV intensity, etc.), the flow rates of the first and second gas supply systems 234 and 244, and the flow rates of the first and second gas injection systems 234 and 244 in order to affect a change in the uniformity of the oxidation or nitridation process. The controller 260 can be configured to independently control each of the second radical sources 240 relative to one another. The controller 260 can be configured to independently control each of the second gas injection systems 244 relative to one another. Alternatively, or additionally, the controller 260 can be configured to control any other parameter of the treatment chamber 210. For example, controller 260 can control pumping system 250.

A plurality of first radical sources 230 may be used, including 2, 3, 4, 5, or 6 first radical sources 230. Similarly, more than one second radical source 240 may be used, including 2, 3, 4, 5, 6, or 7 second radical sources 240. Each radical source may be independently controlled with the controller 260. More than one controller 260 may be used.

Substrate 225 rests on top substrate holder 220. It may or may not be clamped. It may be temperature controlled. Substrate 225 can be rotated to improve uniformity azimuthally.

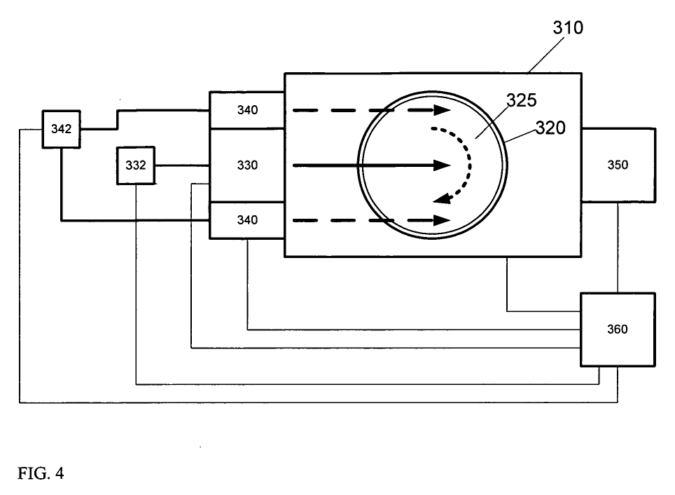

FIG. 4 illustrates a schematic top view of one embodiment of a processing system for forming a layer or treating a substrate. The processing system may be configured to perform an oxidation, nitridation, oxynitridation, or other treatment of a substrate 325. The processing system comprises a treatment chamber 310, a substrate holder 320 configured to support substrate 325, a first radical source 330 configured to introduce a first flow of one or more radicals to a substantially central portion of substrate 325, a second radical source 340 configured to introduce a second flow of one or more radicals to a substantially edge portion of substrate 325, a pumping system 350, and a controller 360. The first radical source 330 includes a first remote plasma source. A first gas supply system 332 is configured to supply a first process gas to the first remote plasma source, and a first flow of radicals is introduced to treatment chamber 310 through a first gas injection system (e.g., a gas injection rake). The second radical source 340 includes a second remote plasma source. A second gas supply system 342 is configured to supply a second process gas to the second remote plasma source, and a second flow of radicals is introduced to treatment chamber 310 through a second gas injection system (e.g., a gas injection rake).

Substrate 325 rests on top of substrate holder 320. It may or may not be clamped. It may be temperature controlled. Substrate 325 can be rotated to improve uniformity azimuthally.

The controller 360 can, for example, be configured to control one or more of the intensity or power of the first radical source 330, the intensity or power of the second radical source 340 in order to affect a change in the uniformity of the oxidation or nitridation process. Alternatively, or additionally, the controller 360 may be configured to control any other parameter of the treatment chamber 310. The controller 360 can also be configured to independently control each of the second radical sources 340 relative to one another. A plurality of first radical sources 330 may be used, including 2, 3, 4, 5, or 6 first radical sources 330. Similarly, more than one second radical source 340 may be used, including 2, 3, 4, 5, 6, or 7 second radical sources 340. Each radical source may be independently controlled with the controller 360. Controller 360 can also control pumping system 350. More than one controller 360 may be used.

The first and second radical flows from the first and second radical sources 330 and 340 may each independently include any radicals, oxygen radicals, nitrogen radicals, molecular radicals of oxygen and nitrogen, or any combination thereof, to effect oxidation, nitridation, oxynitridation, other treatment, or any combination thereof.

The first and second gas supply systems, 332 and 342 may be independently configured to introduce one or more than one process gas. Examples of process gases include, for example, O₂ for an oxidation process, N₂ for a nitridation process, or N₂ and O₂, NO, NO₂, or N₂O, or any combination, for both an oxidation and a nitridation process. A plurality of first and second gas supply systems 332 and 342 may be used, which include 2, 3, 4, 5, or 6 first gas supply system 332 and 2, 3, 4, 5, or 6 second gas supply system 342.

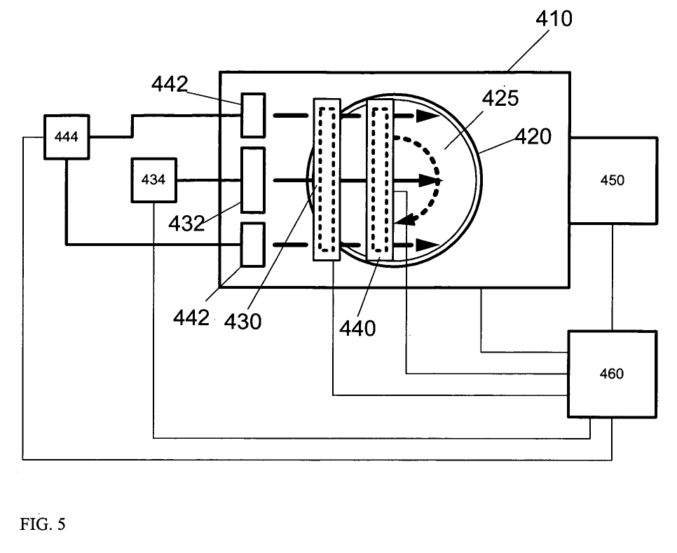

FIG. 5 illustrates a schematic top view of one embodiment of a processing system for forming a layer or treating a substrate. The processing system may be configured to perform an oxidation, nitridation, oxynitridation, or other treatment of a substrate 425. The processing system comprises a treatment chamber 410, a substrate holder 420 configured to support substrate 425, a first radical source 430 configured to introduce a first flow of one or more radicals to a substantially edge portion of substrate 425, a second radical source 440 configured to introduce a second flow of one or more radicals to a substantially central portion of substrate 425, a pumping system 450, and a controller 460. A first gas supply system 444 is configured to supply a first process gas to treatment chamber 410 through a first gas injection system 442 (e.g., a gas injection rake). Additionally, a second gas supply system 434 is configured to supply a second process gas to treatment chamber 410 through a second gas injection system 432 (e.g., a gas injection rake).

The first radical source 430 may include a first array of UV lamps (e.g., the array of UV lamps may include one or more lamps, including 2, 3, 4, 5, 6, 7, or 8 lamps). A plurality of UV lamp arrays are possible, including 2, 3, 4, 5, 6, 7, or 8 arrays). In one embodiment, the processing system is configured such that the first flow of radicals is generated by UV radiation induced dissociation of the first process gas or the second process gas or both by the UV lamps. Alternatively, or additionally, the first radical source 430 can include one or more non-UV radical sources, such as one or more remote or local plasma induced dissociation sources, or other radical source described herein.

The second radical source 440 may include a second array of UV lamps (e.g., the array of UV lamps may include one or more lamps, including 2, 3, 4, 5, 6, 7, or 8 lamps). A plurality of UV lamp arrays are possible, including 2, 3, 4, 5, 6, 7, or 8 arrays). In one embodiment, the processing system is configured such that the second flow of radicals is generated by UV radiation induced dissociation of the first process gas or the second process gas or both by the UV lamps. Alternatively, or additionally, the second radical source 440 can include one or more non-UV radical sources, such as one or more remote or local plasma induced dissociation sources, or other radical source described herein.

Alternatively, the second gas supply system 444 further comprises a third radical source for introducing a third flow of radicals to substrate 425. For example, the third radical source can include one or more non-UV radical sources, such as one or more remote or local plasma induced dissociation sources.

A plurality of first and second gas supply systems 434 and 444 can independently be used, which can include 2, 3, 4, 5, or 6 first gas supply system 434, and 2, 3, 4, 5, or 6 second gas supply systems 444. A plurality of first and second gas injection systems 432 and 442 can be used, which can include 2, 3, 4, 5, or 6 first gas injection system 432, and 2, 3, 4, 5, or 6 second gas injection systems 442.

The first and second radical flows and the optional third radical flow may each independently include any radicals, oxygen radicals, nitrogen radicals, molecular radicals of oxygen and nitrogen, or any combination thereof, to effect oxidation, nitridation, oxynitridation, other treatment, or any combination thereof.

The first and second gas supply and gas injection systems, 432, 442, 434, 444, may be independently configured to introduce one or more than one process gas. Examples of process gases include, for example, O₂ for an oxidation process, N₂ for a nitridation process, or N₂ and O₂, NO, NO₂, or N₂O, ammonia, or any combination thereof, for both an oxidation and a nitridation process.

The controller 460 can, for example, be configured to individually control the first and second radical sources 430 and 440 (e.g., UV intensity, etc.), the flow rates of the first and second gas supply systems 434 and 444, and the flow rates of the first and second gas injection systems 432 and 442 in order to affect a change in the uniformity of the oxidation or nitridation process. Additionally, the controller 460 can, for example, be configured to individually control the third radical source. The controller 460 can be configured to independently control each of the second radical sources 440 relative to one another. The controller 460 can be configured to independently control each of the second gas injection systems 444 relative to one another. Alternatively, or additionally, the controller 460 can be configured to control any other parameter of the treatment chamber 410. For example, controller 460 can control pumping system 450.

A plurality of first radical sources 430 may be used, including 2, 3, 4, 5, or 6 first radical sources 430. Similarly, more than one second radical source 440 may be used, including 2, 3, 4, 5, 6, or 7 second radical sources 440. Each radical source may be independently controlled with the controller 460. More than one controller 460 may be used.

Substrate 425 rests on top substrate holder 420. It may or may not be clamped. It may be temperature controlled. Substrate 425 can be rotated to improve uniformity azimuthally.

The first and second radical flows may be generated remotely or upstream of the substrate 125, 225, 325, or 425 with first and second radical sources 130, 140, 230, 240, 330, 340, 430, 440. Any radical source may be used to generate the radicals by UV radiation induced dissociation and/or plasma induced dissociation of the process gas. Suitable remote and/or upstream radical sources include Radio Frequency (RF) plasma, inductively coupled plasma, plasma torch, capacitively coupled plasma, microwave plasma, capacitive microwave plasma, microwave induced plasma, slot plane antenna plasma, microwave slot plane antenna plasma, UV lamps, surface wave plasma, or helicon wave plasma, or combinations thereof, or the like. One or more than one source may be used. Examples of commercial remote plasma sources include the ASTRON® sources commercially available from MKS Instruments, Inc., ASTeX® Products (90 Industrial Way, Wilmington, Mass. 01887), and TRIA™ SPA processing systems commercially available from Tokyo Electron Limited, Akasaka, Japan.

Alternatively, the first and second radical flows may be established by flowing first and second process gases across the substrate 125, 225, 325, or 425 and generating first and second radicals locally with UV radiation induced dissociation and/or plasma induced dissociation of the process gas. Suitable local radical sources include Radio Frequency (RF) plasma, inductively coupled plasma, plasma torch, capacitively coupled plasma, microwave plasma, capacitive microwave plasma, microwave induced plasma, slot plane antenna plasma, microwave slot plane antenna plasma, UV lamps, surface wave plasma, or helicon wave plasma, or combinations thereof, or the like.

The process chamber 110, 210, 310, and 410 may be configured such that the radicals and/or process gas flows across the respective center and edge portions of the substrate 125, 225, 325, and 425 within a flow that is parallel or substantially parallel to the substrate surface, e.g., in a laminar flow. This may be accomplished by locating the radical source 130, 140, 230, 240, 330, 340, 430 and 440 and/or gas supply system 234, 244, 434 and 444 opposite the pumping system 150, 250, 350, and 450. The process gas and/or radicals flow across the substrate 125, 225, 325, and 425 in the processing chamber 110, 210, 310, and 410 within a flow that is parallel or substantially parallel to the substrate surface, e.g., in a laminar flow and are evacuated from the processing chamber 110, 210, 310, and 410 by the pumping system 150, 250, 350, and 450.

The substrate 125, 225, 325, and 425 can comprise a silicon or other substrate; and the oxide layer can comprise a silicon oxide layer formed via oxidation of the substrate, a silicon nitride layer formed via nitridation of the substrate, an oxynitride layer formed via oxynitridation of the substrate, or any combination thereof. The substrate surface can be any surface, a silicon surface, an oxide surface, a silicon oxide surface, or any combination thereof.

For example, an oxidation, nitridation, or oxynitridation process may be performed on a substrate having a bare silicon surface, whereby a silicon oxide, silicon nitride, or silicon oxynitride film is formed on the silicon surface, respectively. The treatment system of FIG. 2, 3, 4 or 5 can be utilized to monitor, adjust, or control the spatial uniformity of the respective film formed on the silicon surface. Alternatively, for example, an oxidation, nitridation, or oxynitridation process may be performed on a silicon oxide film, silicon nitride film, or silicon oxynitride film in order to correct or improve the uniformity of the respective film using the treatment system of FIG. 2, 3, 4 or 5. In a thermal treatment system, the silicon oxide film may be formed using a thermal oxidation process in an oxygen ambient, the silicon nitride film may be formed using a thermal nitridation process in a nitrogen ambient, such as an ammonia atmosphere, and the silicon oxynitridation film may be formed in an oxygen and nitrogen ambient.

The substrate 125, 225, 325, and 425 can be rotated in the plane of the substrate surface at a rate of about 1 rpm to about 60 rpm, which includes 1, 2, 3, 4, 5, 6, 7, 8, 9, 10, 11, 12, 13, 14, 15, 16, 17, 18, 19, 20, 30, 40, 50, or 60 rpm, or any combination thereof.

At least one property of the first flow of radicals and at least one property of the second flow of radicals can be set to control the spatial variations of the treatment of the substrate surface. In fact, the treatment can be made uniform. Both the center and the edge portions of substrate 125, 225, 325, and 425 can be exposed to the first flow of radicals, while the center portion is not exposed to the second flow of radicals.

The processing system may be configured to process 200 mm substrates, 300 mm substrates, or larger-sized substrates. It is contemplated that the processing system may be configured to process substrates, wafers, or LCDs regardless of their size, as would be appreciated by those skilled in the art. Therefore, while aspects of the invention will be described in connection with the processing of a semiconductor substrate, the invention is not limited solely thereto.

The temperature of the substrate 125, 225, 325, and 425 may be raised, lowered, and otherwise controlled by the controller 160, 260, 360, and 460 via suitable temperature control elements, such as a heating system that may comprise resistive heating elements, thermo-electric heaters/coolers, re-circulating coolant flow that receives heat from substrate holder 120, 220, 320, and 420 and transfers heat to a heat exchanger system (not shown), or when heating, transfers heat from the heat exchanger system to the substrate 125, 225, 325, and 425. Furthermore, the temperature of the substrate may be controlled with temperature control elements disposed in the chamber wall of the process chamber 110, 210, 310, and 410 and/or any other component within the processing system.

In order to improve the thermal transfer between substrate 125, 225, 325, and 425 and substrate holder 120, 220, 320, and 420, the substrate holder 120, 220, 320, and 420 can include a mechanical clamping system, or an electrical clamping system, such as an electrostatic clamping system, to affix substrate 125, 225, 325, and 425 to an upper surface of substrate holder 120, 220, 320, and 420. Furthermore, substrate holder 120, 220, 320, and 420 can further include a substrate backside gas delivery system configured to introduce gas to the backside of substrate 125, 225, 325, and 425 in order to improve the gas-gap thermal conductance between substrate 125, 225, 325, and 425 and substrate holder 120, 220, 320, and 420. Such a system can be utilized when temperature control of the substrate is required at elevated or reduced temperatures. For example, the substrate backside gas system can comprise a two-zone gas distribution system, wherein the helium gas gap pressure can be independently varied between the center and the edge of substrate 125, 225, 325, and 425.

The pumping system 150, 250, 350, and 450 may include one or more of a pressure control system, vacuum pump, valve, duct (not shown). The pumping system 150, 250, 350, and 450 is configured to controllably evacuate the process chamber 110, 210, 310, and 410 to a pressure suitable for forming the thin film on substrate 125, 225, 325, and 425. The pumping system 150, 250, 350, and 450 can include a turbo-molecular vacuum pump (TMP) capable of a pumping speed up to about 5000 liters per second (and greater), and valve can include a gate valve for throttling the chamber pressure. In conventional plasma processing devices, pumping speeds of about 500 to about 3000 liter per second using TMP are generally employed. Moreover, a device for monitoring chamber pressure (not shown) can be coupled to the processing chamber 110, 210, 310, and 410. The pressure measuring device can be, for example, a Type 628B Baratron absolute capacitance manometer commercially available from MKS Instruments, Inc. (Andover, Mass.).

Additionally, the controller 160, 260, 360, and 460 may be independently coupled to one or more of the process chamber 110, 210, 310, and 410; substrate holder 120, 220, 320, and 420; first and second radical sources 130, 140, 230, 240, 330, 340, 430, and 440; first and second gas injection systems 232, 242, 432 and 442; first and second gas supply systems 234, 244, 334, 344, 434 and 444; and/or pumping systems 150, 250, 350, and 4350. Alternately, or in addition, controller 160, 260, 360, and 460 can be coupled to one or more additional controllers/computers (not shown), and can obtain setup and/or configuration information from an additional controller/computer.

Singular processing elements (160, 260, 360, 460, 110, 210, 310, 410, 120, 220, 320, and 420, 130, 140, 230, 240, 330, 340, 430, 440, 234, 244, 232, 242, 332, 342, 432, 434, 442, 444, 150, 250, 350, and 450) are shown, but are not required for the invention. The processing system can comprise any number of processing elements having any number of controllers associated with them in addition to independent processing elements.

The controller 160, 260, 360, and 460 can be used to configure any number of processing elements (110, 210, 310, 410, 120, 220, 320, and 420, 130, 140, 230, 240, 330, 340, 430, 440, 234, 244, 232, 242, 332, 342, 432, 434, 442, 444, 150, 250, 350, and 450), and the controller 160, 260, 360, and 460 can collect, provide, process, store, and display data from processing elements. The controller 160, 260, 360, and 460 can comprise a number of applications for controlling one or more of the processing elements. For example, controller 160, 260, 360, and 460 can include a graphic user interface (GUI) component (not shown) that can provide easy to use interfaces that enable a user to monitor and/or control one or more processing elements. The controller 160, 260, 360, and 460 can comprise a microprocessor, memory, and a digital I/O port capable of generating control voltages sufficient to communicate and activate inputs to processing system as well as monitor outputs from processing system. For example, a program stored in the memory may be utilized to activate the inputs to the aforementioned components of the processing system according to a process recipe in order to perform process. The controller 160, 260, 360, and 460 may be implemented as a UNIX-based workstation. Alternately, the controller 160, 260, 360, and 460 can be implemented as a general-purpose computer, digital signal processing system, etc. One example of the controller 160, 260, 360, and 460 is a DELL PRECISION WORKSTATION 610™, available from Dell Corporation, Austin, Tex.

The controller 160, 260, 360, and 460 may be locally located relative to the processing system, or it may be remotely located relative to the processing system. For example, the controller 160, 260, 360, and 460 may exchange data with the processing system using at least one of a direct connection, an intranet, the Internet and a wireless connection. The controller 160, 260, 360, and 460 may be coupled to an intranet at, for example, a customer site (i.e., a device maker, etc.), or it may be coupled to an intranet at, for example, a vendor site (i.e., an equipment manufacturer). Additionally, for example, the controller 160, 260, 360, and 460 may be coupled to the Internet. Furthermore, another computer (i.e., controller, server, etc.) may access, for example, the controller 160, 260, 360, and 460 to exchange data via at least one of a direct connection, an intranet, and the Internet. As also would be appreciated by those skilled in the art, the controller 160, 260, 360, and 460 may exchange data with the processing system via a wireless connection.

The locations of the first and second radical sources 130, 140, 230, 240, 330, 340, 430, and 440 relative to the central and edge portions of the substrate 125, 225, 325, and 425 may be determined by considering the portion of the substrate 125, 225, 325, and 425 that mainly interacts with the respective radicals produced by the radical sources. For example, the radicals that result from that radical source located near the edge portion of the substrate 125, 225, and 325 will mainly contact the edge portion of the substrate 125, 225, 325, and 425. The radicals that result from the radical source located near the center portion of the substrate 125, 225, 325, and 425 will mainly contact the center portion of the substrate 125, 225, 325, and 425, but they may also contact the edge portion. The edge portion and the center portion of the substrate 125, 225, 325, and 425 may be defined with respect to the planar or substantially planar surface of the substrate 125, 225, 325, and 425.

The order of exposing the central portions and edge portions of the substrate 125, 225, 325, and 425 to the first and second radical flows may be varied. In one embodiment, the central portion may be exposed first to the first radical flow, and then the edge portion may then be exposed to the second radical flow. In one embodiment, the edge portion may first be exposed to the second radical flow, and then the central portion may then be exposed to the first radical flow. In another embodiment, the central and edge portions are exposed to the respective first and second radical flows at about the same time or even simultaneously.

At any point prior to, during, or after the treatment, any of the first and second radical parameters, e.g., flows, may be varied over time, relative to one another, continuously, randomly, periodically, stepwise, smoothly, inversely, one or both may stop, they may both increase, or they may both decrease, or any combination thereof.

Any of the elements or process conditions or features mentioned herein with regard to the embodiments in FIG. 1, FIG. 2, FIG. 3, FIG. 4 and/or FIG. 5 may be combined with any other. For example, it is contemplated that the first and second radical sources 130, 140, 330, 340, 430, and 440 and/or first and second gas supply systems 234, 244, 434 and 444 used remotely may be used in combination with the first and second radical sources 230 and 240 used locally, either individually or in combination.

Oxidation and/or Nitridation

Prior to oxidizing, nitriding, oxynitriding, or other treatment, it may be desirable to clean the substrate surface, or remove a native oxide from the substrate surface. This may be accomplished using one or more cleaning steps including wet chemical cleaning, or forming a bare silicon surface on the substrate surface by cleaning followed by contacting the substrate surface with HF, or both.

The substrate 125, 225, 325, and 425 is placed on substrate holder 120, 220, 320, or 420. Conditions in the treatment chamber 110, 210, 310, and 410 (e.g., pressure, temperature, substrate rotation, etc.) are brought to the desired values. The chamber may be purged. A radical species is introduced into the treatment chamber 110, 210, 310, and 410. The radical species may be remotely generated (e.g., by a source external to or attached to the treatment chamber 110, 210, 310, and 410) and then introduced into the treatment chamber 110, 210, 310, and 410. Alternatively, or additionally, the radical species may be locally generated by the local dissociation (e.g., within the treatment chamber 110, 210, 310, and 410 or in any case nearer to the substrate surface) of a process gas flowing within the treatment chamber 110, 210, 310, 410 and/or across the substrate 125, 225, 325, and 425. A combination of remote and local radical generation may be used. In one embodiment, a population of radicals may be enhanced by supplying a molecular composition that contains undissociated process gas molecules into the treatment chamber 110, 210, 310, and 410.

Any radical source may be used. Examples of radical sources include Radio Frequency (RF) plasma, inductively coupled plasma, plasma torch, capacitively coupled plasma, microwave plasma, capacitive microwave plasma, microwave induced plasma, slot plane antenna plasma, microwave slot plane antenna plasma, UV lamps, surface wave plasma, or helicon wave plasma, or combinations thereof, or the like.

The UV radiation induced dissociation and the plasma induced dissociation may be configured to generate radical species from the same or different process gases. The UV radiation induced dissociation and the plasma induced dissociation may be configured to generate radical species concurrently, or in the order of UV radiation induced dissociation then plasma induced dissociation or plasma induced dissociation then UV radiation induced dissociation.

In an oxidation, nitridation, or oxynitridation process, the process gas can include an oxygen and/or nitrogen containing gas, such as, for example, O₂, N₂, NO, NO₂ or N₂O, or any combination thereof. The process gas can be introduced at a flow rate of about 30 sccm to about 5 slm, which includes 30, 35, 40, 45, 50, 55, 60, 65, 70, 75, 80, 85, 90, 100, 250, 275, 300, 400, 500, 600, 700, 800, 900, or 1000 (sccm), 2, 3, 4, or 5 (slm), or any combination thereof. Additionally (not shown), a purge gas or carrier gas can be introduced to process chamber 110, 210, 310, or 410. The purge gas or carrier gas may comprise an inert gas, such as nitrogen or a noble gas (i.e., helium, neon, argon, xenon, krypton). The flow rate of the purge gas can be about 0 slm to about 5 slm, which includes 0, 1, 2, 3, 4, 5, 6, 7, 8, 9, 10, 20, 30, 35, 40, 45, 50, 55, 60, 65, 70, 75, 80, 85, 90, 100, 250, 275, 300, 400, 500, 600, 700, 800, 900, or 1000 (sccm), 2, 3, 4, or 5 (slm), or any combination thereof.

The UV radiation source may be monochromatic or polychromatic. Additionally, the UV source can be configured to produce radiation at a wavelength sufficient for dissociating the process gas, e.g., O₂. In one embodiment, the ultraviolet radiation can have a wavelength from about 145 nm to about 192 nm, which includes 145, 147, 150, 155, 171, 172, 173, 175, 180, 185, 190, and 192 nm as appropriate for the binding energy of the molecule which is dissociated. The UV radiation source can operate at a power of about 5 W/cm² to about 100 mW/cm², which includes 5, 6, 7, 8, 9, 10, 11, 13, 15, 17, 19, 20, 30, 40, 50, 60, 70, 80, 90 or 100 mW/cm², or any combination thereof. More than one UV radiation source may be used, which include 2, 3, 4, 5, 6, or more radiation sources. The sources can include lamps or lasers or a combination thereof.

The inner surface of the process chamber 110, 210, 310, and 410 may be lined with quartz or other material such as a disposable material in order to suppress metal contamination of the substrate 125, 225, 325, and 425 to be processed.

In one example, the substrate 125, 225, 325, and 425 may be exposed to UV radiation from the UV radiation source emitting UV radiation through a quartz window (not shown) into the processing chamber 110, 210, 310, and 410 to illuminate select portions of the substrate 125, 225, 325, and 425. Alternately, the UV radiation source and quartz window may be large enough to cover the entire substrate 125, 225, 325, and 425.

The oxidizing may be carried out for a time of about 5 seconds to about 25 minutes, which includes 5, 10, 15, 20, 25, 30, 35, 40, 50, 60 (seconds), 2, 3, 4, 5, 6, 7, 8, 9, 10, 15, 20, or 25 (minutes).

The oxide film can have a thickness of about 0.1 nm to about 3 nm, which range includes 0.1, 0.2, 0.3, 0.4, 0.5, 0.6, 0.7, 0, 8, 0.9, 1, 1.1, 1.2, 1.3, 1.4, 1.5, 1.6, 1.7, 1.8, 1.9, 2, 2.1, 2.3, 2.4, 2.5, 2.6, 2.7, 2.8, 2.9, or 3.0 nm. The oxide film may have a thickness variation σof about 0.7% to about 4%, which includes 0.7, 0.9, 1, 2, 3, or 4%.

As an alternative to the conditions discussed above, the conditions set out below may be employed. One embodiment of process conditions for UV induced oxidation (UVO²) is given below.

UVO₂

| | | | |
|---|---|---|---|
| Parameter | Typical | Low | High |

| | | | | | | |
|---|---|---|---|---|---|---|
| Pressure | 0.1 | T | 0.01 | T | 20 | T |
| Temperature | 700° | C. | 400° | C. | 800° | C. |
| Gas Ar | 0 | | 0 | | 2 | slm |
| Gas O₂ | 450 | sccm | 100 | sccm | 2 | slm |
| Time | 60 | sec | 10 | sec | 5 | min |

Other suitable processing systems containing a UV radiation source and methods of using are described in European Patent Application EP 1453083 A1, filed Dec. 5, 2002, the entire contents of which are hereby incorporated by reference.

Nitridation or oxidation may also be accomplished using a microwave induced plasma via slot plane antenna microwave (SPA) source. In this embodiment, the nitrogen or oxygen containing molecular composition is dissociated by microwave induced plasma, which has a low electron temperature and high plasma density.

The SPA radicals may be characterized by low electron temperature (less than about 1.5 eV) and high plasma density (e.g., >about 1×10¹²/cm³) for damage-free processing of gate stacks according to one embodiment. The plasma processing system 400 can, for example, include a TRIA™ SPA processing system from Tokyo Electron Limited, Akasaka, Japan.

Alternative SPA Oxidation (SPAO) conditions are set out below:

SPAO

| | | | |
|---|---|---|---|
| Parameter | Typical | Low | High |

| | | | | | | |
|---|---|---|---|---|---|---|
| Pressure | 100 | mT | 10 | mT | 10 | T |
| Temperature | 400° | C. | 25° | C. | 1000° | C. |
| Gas Ar | 1 | slm | 500 | sccm | 10 | slm |
| Gas O₂ | 100 | sccm | 10 | sccm | 1 | slm |
| Gas H₂ | 10 | sccm | 0 | | 1 | slm |
| Time | 15 | sec | 5 | sec | 5 | min |

Any nitrogen or oxygen containing composition is suitable, e.g., any of N₂, NO, N₂O, NO₂, or O₂ alone or in combination. In one embodiment, the molecular composition in the oxidizing, nitriding, or oxynitriding process gas may include O₂ or N₂ and optionally at least one gas selected from the group consisting of H₂, Ar, He, Ne, Xe, or Kr, or any combination thereof. In one embodiment, the molecular composition in the process gas comprises O₂ or N₂ and H₂ and optionally at least one gas selected from the group consisting of H₂, Ar, He, Ne, Xe, or Kr, or any combination thereof. The oxygen or nitrogen containing molecular composition in the process gas may suitably comprise O₂ or N₂, and the oxygen or nitrogen radicals are produced from plasma induced dissociation of the O₂ and/or N₂

The oxynitride film obtained under nitridation of an oxide layer may have a thickness of about 0.1 nm to about 5 nm, which range includes 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.1, 2.3, 2.4, 2.5, 2.6, 2.7, 2.8, 2.9, 3.0, 3.1, 3.2, 3.3, 3.4, 3.5, 3.6, 3.8, 4, 4.1, 4.5, or 5 nm, or any combination thereof. The oxynitride film may have a thickness variation σ of about 0.7% to about 4%, which includes 0.7, 0.9, 1, 2, 3, or 4%.

The nitriding, oxidizing, or oxynitriding may be carried out at a substrate temperature of about 0° C. to about 1000° C., which range includes 10, 20, 30, 40, 50, 60, 70, 80, 90, 100, 125, 150, 175, 200, 225, 250, 275, 300, 325, 350, 375, 400, 450, 500, 550, 600, 650, 700, 750, 800, 850, 900, 950, or 1000° C., or any combination thereof.

The nitriding, oxidizing, or oxynitriding may be carried out at a pressure of about 1 mTorr to about 30,000 mTorr, which includes 1, 2, 3, 4, 5, 6, 7, 8, 9, 10, 20, 30, 40, 50, 60, 70, 80, 90, 100, 250, 500, 750, 1,000, 10,000, 20,000, or 30,000 mTorr, or any combination thereof.

The flow rate of the nitrogen containing molecular composition or oxygen containing molecular composition may range from 2 sccm to 5 slm. These ranges include 2, 3, 4, 5, 6, 7, 8, 9, 10, 20, 30, 35, 40, 45, 50, 55, 60, 65, 70, 75, 80, 85, 90, 100, 250, 275, 300, 400, 500, 600, 700, 800, 900, or 1000 (sccm), 2, 3, 4, or 5 (slm), or any combination thereof.

The nitriding or oxidizing may be carried out for a time of about 5 seconds to about 25 minutes, which range includes 5, 10, 15, 20, 25, 30, 35, 40, 50, 60 (seconds), 2, 3, 4, 5, 6, 7, 8, 9, 10, 15, 20, or 25 (minutes), or any combination thereof.

The oxynitride film may have a surface nitrogen concentration of about 20% or less, which includes 4, 6, 8, 10, 12, 14, 16, 18, and 20% or less.

The nitriding or oxidizing plasma may be generated by a microwave output of about 0.5 W/cm² to about 5 W/cm², which includes 0.5, 0.6, 0.7, 0.8, 0.9, 1, 1.1, 1.3, 1.5, 1.7, 1.9, 2, 3, 4, or 5 W/cm², or any combination thereof.

The microwave irradiation may comprise a microwave frequency of about 300 MHz to about 10 GHz, which includes 300, 400, 500, 600, 700, 800, 900, or 1000 (MHz), 1.5, 2, 2.45, 3, 4, 5, 6, 7, 8, 9, or 10 (GHz).

In one embodiment, the plasma may comprise an electron temperature of less than about 3 eV, which includes 0.1, 0.3, 0.5, 0.7, 0.9, 1, 1.5, 2, 2.5, or 3 eV, or any combination thereof. The plasma may have a density of about 1×10¹¹/cm³ to about 1×10¹³/cm³ or higher, and a density uniformity of about ±3% or less, which includes ±1, ±2, and ±3%.

The plane antenna member may have a surface area on a surface thereof greater than the area of the substrate surface on which the film is deposited.

The oxynitride film may suitably have the formula SiON. The oxide film may have the formula SiO₂.

As an alternative to the nitridation process parameters set forth above, the following parameters can be employed in microwave slot plane antenna nitridation (SPAN):

SPAN

| | | | |
|---|---|---|---|
| Parameter | Typical | Low | High |

| | | | | | | |
|---|---|---|---|---|---|---|
| Pressure | 50 | mT | 10 | mT | 10 | T |
| Temperature | 400° | C | 25° | C. | 800° | C. |
| Gas Ar | 1 | slm | 100 | slm | 5 | slm |
| Gas N₂ | 40 | sccm | 5 | sccm | 1 | slm |
| Time | 20 | sec | 5 | sec | 5 | min |

Other suitable plasma processing systems containing a slot plane antenna plasma source and methods of using are described in European Patent Application EP 1361605 A1, filed Jan. 22, 2002, the entire contents of which are hereby incorporated by reference.

Radical Flow Nitridation (RFN) or Radical Flow Oxidation (RFO) may be employed prior to, concurrently with, or after the UVO₂ oxidizing, SPA oxidizing, or SPA nitriding processes. In RFN, the oxide film (or oxynitride film) may be exposed to nitrogen radicals formed by a remote (or “upstream”) plasma induced dissociation or local plasma induced dissociation of a process gas comprising a molecular composition comprising nitrogen. The upstream or local plasma induced dissociation can be caused by coupling radio frequency power to the process gas.

In RFO, the oxide film may be exposed to oxygen radicals formed by an upstream plasma induced dissociation or local plasma induced dissociation of a process gas comprising an molecular composition comprising oxygen. The upstream or local plasma induced dissociation can be caused by coupling radio frequency power to the process gas.

Example of some process parameters for RFN and RFO are given below:

RFN (Radical Flow Nitridation)

| | | | |
|---|---|---|---|
| Parameter | Typical | Low | High |

| | | | | | | |
|---|---|---|---|---|---|---|
| Pressure | 200 | mT | 10 | mT | 10 | T |
| Temperature | 400° | C. | 25° | C. | 1000° | C. |
| Gas Ar | 1 | slm | 500 | sccm | 10 | slm |
| Gas N₂ | 100 | sccm | 10 | sccm | 1 | slm |
| Time | 60 | sec | 5 | sec | 5 | min |

RFO (Radical Flow Oxidation)

| | | | |
|---|---|---|---|
| Parameter | Typical | Low | High |

| | | | | | | |
|---|---|---|---|---|---|---|
| Pressure | 200 | mT | 10 | mT | 10 | T |
| Temperature | 400° | C. | 25° | C. | 1000° | C. |
| Gas Ar | 1 | slm | 500 | sccm | 10 | slm |
| Gas O₂ | 100 | sccm | 10 | sccm | 1 | slm |
| Time | 60 | sec | 5 | sec | 5 | min |

The plasma oxidation and/or nitridation conditions discussed herein may be used in combination with the UVO₂ oxidation, which plasma oxidation and/or processes may include any of the following, alone or in combination:

exposing the surface to oxygen and/or nitrogen radicals formed by plasma induced dissociation of a process gas comprising at least one molecular composition comprising oxygen and/or nitrogen; and/or

exposing the surface to oxygen and/or nitrogen radicals formed by plasma induced dissociation of a process gas comprising at least one molecular composition comprising oxygen and/or nitrogen, wherein the plasma induced dissociation of the process gas comprises using plasma based on microwave irradiation via a plane antenna member having a plurality of slots.

Any of the process conditions mentioned herein with regard to the embodiments of either FIG. 1, FIG. 2, FIG. 3, FIG. 4, or FIG. 5 may also be applied to any other embodiment.

Simple Annealing

After the subject film is prepared, e.g., the oxide, nitride or oxynitride film, it may be annealed. The anneal suitably anneals the film.

The annealing may be carried out at a pressure of about 5 mTorr to about 800 Torr, which includes 5, 6, 7, 8, 9, 10, 20, 30, 40, 50, 60, 70, 80, 90, 100, 250, 500, 750, 1,000, 10,000, 20,000, 30,000, 50,000, 100,000, 200,000, 400,000, or 800,000 mTorr, or any combination thereof.

The annealing may be carried out at a temperature of about 500° C. to about 1200° C., which includes 500, 550, 600, 650, 700, 750, 800, 850, 900, 950, 1000, 1100, or 1200° C., or any combination thereof.

The annealing may be carried out under an annealing gas comprising at least one molecular composition comprising oxygen, nitrogen, H₂, Ar, He, Ne, Xe, or Kr, or any combination thereof at a flow rate of 0 to 20 slm. In one embodiment, annealing is effected under N₂ at an N₂ flow rate of about 0 slm to about 20 slm, which includes 2, 3, 4, 5, 6, 7, 8, 9, 10, 20, 30, 35, 40, 45, 50, 55, 60, 65, 70, 75, 80, 85, 90, 100, 250, 275, 300, 400, 500, 600, 700, 800, 900, or 1000 (sccm), 2, 3, 4, 5, 10, 15, or 20 (slm), or any combination thereof.

The annealing may be carried out for a time of about 1 second to about 10 minutes, which range includes 1, 2, 3, 4, 5, 6, 7, 8, 9, 10, 15, 20, 25, 30, 35, 40, 50, 60 (seconds), 2, 3, 4, 5, 6, 7, 8, 9, or 10 (minutes), or any combination thereof.

The annealing and the treating may be carried out in the same process chamber, in which case it is possible to carry out at least one purging step is carried out after the treating and prior to the annealing. Of course, it is also possible to carry out treating and the annealing in different process chambers. In this embodiment, it is possible to transfer the film-bearing substrate from one chamber to another without contacting ambient atmosphere, air, etc.

Alternatively, the following conditions may be employed for an anneal:

Simple Anneal

| | | | |
|---|---|---|---|
| Parameter | Typical | Low | High |

| | | | | | | |
|---|---|---|---|---|---|---|
| Pressure | 1 | T | 50 | mT | 760 | T |
| Temperature | 1000° | C. | 800° | C. | 1100° | C. |
| Gas N₂ | 1 | slm | 0 | | 10 | slm |
| Gas O₂ | 1 | slm | 0 | | 10 | slm |
| Time | 15 | sec | 5 | sec | 5 | min |

UVO₂/N₂ Anneal

As an alternative anneal after the film is prepared, UVO₂/N₂ anneal can be employed by exposing the oxide, nitride or oxynitride film to oxygen radicals and nitrogen radicals formed by UV radiation induced dissociation of an annealing gas comprising at least one molecular composition comprising oxygen and nitrogen. The oxygen and nitrogen radicals are dissociated from an annealing gas comprising at least one molecular composition comprising oxygen and nitrogen selected from the group consisting of O₂, N₂, NO, NO₂, and N₂O, or any combination thereof. Other gases may be present for example one or more of H₂, Ar, He, Ne, Xe, or Kr, or any combination thereof.

In one embodiment of this anneal, the annealing gas flows across the oxide or oxynitride surface such that the oxygen and nitrogen radicals are comprised within a laminar flow of the annealing gas across the surface.

The annealing may be carried out at a pressure of about 1 mTorr to about 80,000 mTorr, which includes 1, 2, 3, 4, 5, 6, 7, 8, 9, 10, 20, 30, 40, 50, 60, 70, 80, 90, 100, 250, 500, 750, 1,000, 10,000, 20,000, 30,000, 50,000, 100,000, 200,000, 400,000, or 800,000 mTorr, or any combination thereof.

The annealing may be carried out at a temperature of about 400° C. to about 1200° C., which includes 500, 550, 600, 650, 700, 750, 800, 850, 900, 950, 1000, 1100, or 1200° C., or any combination thereof.

The annealing gas may have a flow rate of about 0 slm to about 20 slm, which includes 0, 1, 2, 3, 4, 5, 6, 7, 8, 9, 10, 20, 30, 35, 40, 45, 50, 55, 60, 65, 70, 75, 80, 85, 90, 100, 250, 275, 300, 400, 500, 600, 700, 800, 900, or 1000 (sccm), 2, 3, 4, 5, 10, 15, or 20 (slm), or any combination thereof.

The annealing may be carried out for a time of about 1 second to about 10 minutes, which range includes 1, 2, 3, 4, 5, 6, 7, 8, 9, 10, 15, 20, 25, 30, 35, 40, 50, 60 (seconds),2, 3, 4, 5, 6, 7, 8, 9, or 10 (minutes).

The ultraviolet radiation during this anneal may include wavelengths of about 145 nm to about 192 nm, which includes 145, 147, 150, 155, 171, 172, 173, 175, 180, 185, 190, or 192 nm, or any combination thereof, as appropriate for the binding energy of the molecule which is dissociated. The radiation may be monochromatic or polychromatic.

It may originate from an ultraviolet radiation source operating at a power of about 5 mW/cm² to about 100 mW/cm², which includes 5, 6, 7, 8, 9, 10, 11, 13, 15, 17, 19, 20, 30, 40, 50, 60, 70, 80, 90 or 100 W/cm², or any combination thereof. One or more ultraviolet sources may be used.

The annealing and the oxidizing/nitriding may be carried out in the same process chamber, in which case it is possible to carry out at least one purging step after the nitriding and prior to the annealing. It is also possible to carry out oxidizing/nitriding and the annealing in different process chambers. In this embodiment, it is possible to transfer the film-bearing substrate from one chamber to another without contacting ambient atmosphere, air, etc.

RFN Anneal

As an alternative anneal after the film is prepared, an RFN anneal can be employed to anneal the oxide, nitride or oxynitride film by exposing the film to nitrogen radicals formed by an upstream plasma induced dissociation of an upstream annealing gas comprising an upstream molecular composition comprising nitrogen. The upstream plasma induced dissociation can be caused by coupling radio frequency power to the upstream annealing gas. The nitrogen radicals can flow across the surface within a flow that is parallel or substantially parallel to the surface, e.g., a laminar manner.

The annealing may be suitably carried out at a pressure of about 1 mTorr to about 20,000 mTorr, which includes 1, 2, 3, 4, 5, 6, 7, 8, 9, 10, 20, 30, 40, 50, 60, 70, 80, 90, 100, 250, 500, 750, 1,000, 10,000, 20,000 mTorr, or any combination thereof.

The annealing may be suitably carried out at a substrate temperature of about 20° C. to about 1200° C., which includes 20, 30, 40, 50, 60, 70, 80, 90, 100, 200, 300, 400, 500, 550, 600, 650, 700, 750, 800, 850, 900, 950, 1000, 1100, or 1200° C., or any combination thereof.

The annealing may be carried out is carried out for a time of about 1 second to about 25 min, which range includes 1, 2, 3, 4, 5, 6, 7, 8, 9, 10, 15, 20, 25, 30, 35, 40, 50, 60 (seconds), 2, 3, 4, 5, 6, 7, 8, 9, 10, 15, or 20 (minutes).

The annealing may be carried out under N₂ at an N₂ flow rate of about 2 sccm to about 20 slm, which includes 0, 1, 2, 3, 4, 5, 6, 7, 8, 9, 10, 20, 30, 35, 40, 45, 50, 55, 60, 65, 70, 75, 80, 85, 90, 100, 250, 275, 300, 400, 500, 600, 700, 800, 900, or 1000 (sccm), 2, 3, 4, 5, 10, 15, or 20 (slm), or any combination thereof.

The annealing may also be carried out in the presence of other gases, for example, H₂, Ar, He, Ne, Xe, or Kr, or any combination thereof. The flow rate of these other gases may be about 100 sccm to about 20 slm, which includes 100, 250, 275, 300, 400, 500, 600, 700, 800, 900, or 1000 (sccm), 2, 3, 4, 5, 10, 15, or 20 (slm), or any combination thereof.

The annealing may be carried out using plasma remotely generated via the coupling of radio frequency (RF) power having a frequency of about 40 kHz to about 4 MHz with the upstream annealing gas, which includes 40, 50, 60, 70, 80, 90, 100, 200, 300, 400, 500, 600, 700, 800, 900, or 1000 (kHz), 1.5, 2, 3, or 4 (MHz), or any combination thereof.

Device Fabrication

One embodiment includes forming a semiconductor device including a poly-silicon, amorphous-silicon, or SiGe layer, or any combination thereof, on an oxide film, a nitride film, an oxynitride film, or any combination thereof.

Another embodiment includes making a semiconductor or electronic device with the present method and system.

The processes can be performed on a thin oxide formed during a wet chemical clean, e.g., chemical oxide, or on a bare Si surface formed by a clean in which the last step is a HF dip to remove all oxide.

Other suitable systems and methods are described in the following references, the entire contents of each of which are independently incorporated by reference:

JP 2001-012917, filed Jan. 22, 2001;

JP 2001-374631, filed Dec. 7, 2001;

JP 2001-374632, filed Dec. 7, 2001;

JP 2001-374633, filed Dec. 7, 2001;

JP 2001-401210, filed Dec. 28, 2001;

JP 2002-118477, filed Apr. 19, 2002;

US 2004/0142577 A1, filed Jan. 22, 2002; and

US 2003/0170945 A1, filed Dec. 6, 2002.

The present invention is not limited to the above embodiments and may be practiced or embodied in still other ways without departing from the scope and spirit thereof.

What is claimed is:

1. A method of treating a substrate surface, the surface having a center portion and an edge portion, the method comprising:
exposing the center portion to first radicals produced by a first radical source; and
exposing the edge portion to second radicals produced by a second radical source;
wherein the first and second radicals flow substantially parallel to the surface and at least one property of the edge portion exposing and at least one property of the center portion exposing are set to control the spatial variation of the treatment of the substrate surface.

2. The method of claim 1, wherein the at least one property of the edge portion exposing and the at least one property of the center are set so that the treatment is uniform.

3. The method of claim 1, wherein the center portion is exposed to the first radicals before the edge portion is exposed to the second radicals.

4. The method of claim 1, wherein the edge portion is exposed to the second radicals before the center portion is exposed to the first radicals.

5. The method of claim 1, wherein the center portion and edge portion are exposed contemporaneously.

6. The method of claim 1, wherein the at least one property of the center portion exposing comprises a flow rate of the first radicals, an electron temperature of the first radicals, a composition of the first radicals, a power input of the first radical source, a UV intensity of the first radical source, a UV wavelength of the first radical source, a frequency of the first radical source, or a density of the first radicals, or a combination thereof.

7. The method of claim 1, wherein the at least one property of the edge portion exposing comprises a flow rate of the second radicals, an electron temperature of the second radicals, a composition of the second radicals, a power input of the second radical source, a UV intensity of the second radical source, a UV wavelength of the second radical source, a frequency of the second radical source, or a density of the second radicals, or a combination thereof.

8. The method of claim 1, wherein the treating comprises forming a film on at least a part of the surface, or removing a film from at least a part of the surface, or both.

9. The method of claim 1, wherein the treating comprises forming a film on at least a part of the surface.

10. The method of claim 1, wherein the treating comprises forming a film on at least a part of the surface, wherein the center portion exposing and the edge portion exposing cause film thickness, film uniformity, or film composition, or any combination thereof, to vary spatially over the surface.

11. The method of claim 1, wherein the treating comprises forming an oxide film on at least a part of the surface, and wherein the center portion exposing and the edge portion exposing cause uniformity of oxygen concentration in the oxide film, depth of the oxide film, or thickness of the oxide film, or any combination thereof, to vary spatially over the surface.

12. The method of claim 1, wherein the substrate surface is a silicon surface, an oxide surface, a silicon oxide surface, an oxynitride surface, a nitride surface, or a silicon nitride surface, or any combination thereof.

13. The method of claim 1, wherein the first radicals, or the second radicals, or both, comprise oxygenradicals.

14. The method of claim 1, wherein the first radicals, or the second radicals, or both, comprise nitrogen radicals.

15. The method of claim 1, wherein the first radicals or the second radicals or both flow in a laminar flow across the substrate surface.

16. The method of claim 1, further comprising rotating the substrate in a plane of the substrate surface at a rate of about 1 to about 60 rpm.

17. The method of claim 1, wherein the treating is carried out at a substrate temperature of about 25° to about 1200° C.

18. The method of claim 1, wherein the treating is carried out at a pressure of about 1 mT to about 800 T.

19. The method of claim 1, wherein the first radical source or the second radical source, or both, generates radicals by plasma induced dissociation of at least one process gas or UV induced dissociation of at least one process gas, or both.

20. The method of claim 1, wherein the first radical source or the second radical source, or both, generates radicals by plasma induced dissociation of at least one process gas, and wherein the plasma induced dissociation comprises the local, remote or upstream generation of at least one plasma including Radio Frequency (RF) plasma, inductively coupled plasma, plasma torch, capacitively coupled plasma, microwave plasma, capacitive microwave plasma, microwave induced plasma, or slot plane antenna plasma, surface wave plasma or helicon wave plasma, or any combination thereof.

21. The method of claim 1, wherein the first radical source or the second radical source, or both, generates radicals by plasma induced dissociation of at least one process gas, and wherein the plasma induced dissociation comprises the local, remote or upstream generation of at least one Radio Frequency (RF) plasma.

22. The method of claim 1, wherein the first radical source or the second radical source, or both, generates radicals by plasma induced dissociation of at least one process gas, and wherein the plasma induced dissociation comprises the local, remote or upstream generation of at least one plasma by microwave irradiation of at least one process gas via a plane antenna member having a plurality of slots.

23. The method of claim 1, wherein the first radical source or the second radical source, or both, generates radicals by plasma induced dissociation of at least one process gas comprising O₂, N₂, NO, NO₂, or N₂O, or any combination thereof, and optionally H₂, Ar, He, Ne, Xe, or Kr, or any combination thereof.

24. The method of claim 1, wherein the first radical source or the second radical source, or both, generates radicals by plasma induced dissociation of at least one process gas, and wherein the plasma in the plasma induced dissociation has an electron temperature of less than about 3 eV.

25. The method of claim 1, wherein the first radical source or the second radical source, or both, generates radicals by plasma induced dissociation of at least one process gas, and wherein the plasma in the plasma induced dissociation has a density of about 1×10¹¹ to about 1×10¹³ cm⁻³ and density uniformity of ±3% or less.

26. The method of claim 1, wherein the first radical source or the second radical source, or both, generates radicals by plasma induced dissociation of at least one process gas, wherein the plasma induced dissociation comprises the local, remote or upstream generation of at least one plasma by microwave irradiation of at least one process gas via a plane antenna member having a plurality of slots.

27. The method of claim 1, wherein the first radical source or the second radical source, or both, generates radicals by UV radiation induced dissociation of at least one process gas.

28. The method of claim 1, wherein the first radical source or the second radical source, or both, generates radicals by UV radiation induced dissociation of at least one process gas, wherein the UV radiation comprises 172 nm radiation.

29. The method of claim 1, wherein the first radical source or the second radical source, or both, generates radicals by UV radiation induced dissociation of at least one process gas, wherein the UV radiation originates from two or more ultraviolet radiation sources.

30. The method of claim 1, wherein the first radical source or the second radical source, or both, generates radicals by UV radiation induced dissociation of at least one process gas comprising O₂, N₂, NO, NO₂, or N₂O, or any combination thereof, and optionally H₂, Ar, He, Ne, Xe, or Kr, or any combination thereof.

31. The method of claim 1, further comprising more than one first radical source.

32. The method of claim 1, further comprising more than one second radical source.

33. The method of claim 1, wherein the edge portion is also exposed to the first radicals, and the center portion is not exposed to the second radicals.

34. The method of claim 1, wherein the treating comprises forming a film selected from the group consisting of oxide film, silicon oxide film, oxynitride film, silicon nitride film, nitride film, poly-silicon, amorphous-silicon, SiGe, or any combination thereof.

35. The method of claim 1, further comprising, prior to the treating, carrying out at least one cleaning step, including wet chemical cleaning or forming a bare silicon surface on the substrate surface by cleaning followed by contacting the substrate surface with HF or removing a native oxide from the substrate surface or removing SiO₂ from the substrate surface, or any combination thereof.

36. A method for making a semiconductor or electronic device, comprising the method of claim 1.

37. A processing system for treating a substrate surface, comprising:
means for exposing a central portion of the substrate surface to first radicals in a flow substantially parallel to the substrate surface; and
means for exposing an edge portion of the substrate surface to second radicals in a flow substantially parallel to the substrate surface;
wherein at least one property of the edge portion exposing and at least one property of the center portion exposing are set to control the spatial variation of the treatment of the substrate surface.

38. The processing system of claim 37, wherein the flow of first radicals and the flow of second radicals are substantially parallel to each other.

39. A processing system for treating a substrate surface, the surface having a center portion and an edge portion, the system comprising:
a first radical source configured to expose the center portion to first radicals in a flow substantially parallel to the surface; and
a second radical source configured to expose the edge portion to second radicals in a flow substantially parallel to the substrate surface;
wherein at least one property of the edge portion exposing and at least one property of the center portion exposing are set to control the spatial variation of the treatment of the substrate surface.

40. The processing system of claim 39, wherein the flow of first radicals and the flow of second radicals are substantially parallel to each other.
